(19) United States
(12) Patent Application Publication
(10) Pub. No.: US 2008/0156260 A1
(43) Pub. Date: Jul. 3, 2008

(54) Wafer Support and Method of Making Wafer Support

(75) Inventors: Larry W. Shive, St. Charles, MO (US); Brian L. Gilmore, O'Fallon, MO (US)

Correspondence Address: SENNIGER POWERS LLP, ONE METROPOLITAN SQUARE, 16TH FLOOR, ST LOUIS, MO, 63102, US

(73) Assignee: MEMC ELECTRONIC MATERIALS, INC., St. Peters, MO (US)

(21) Appl. No.: 11/616,485

(22) Filed: Dec. 27, 2006

(51) Int. Cl. C23C 16/02; B05C 13/00

(52) U.S. Cl. 118/500; 427/255.28

(57) ABSTRACT

A wafer support platform is sandblasted with silicon-containing particles to create a surface with uniform roughness. Contaminants become embedded in the surface during the sandblasting procedure. A layer is applied over the surface to isolate the contaminants from a support wafer while maintaining the uniform roughness.

### FIELD OF THE INVENTION

The present invention generally relates to a wafer support for supporting a semiconductor wafer during treatment and to methods of making wafer supports.

### BACKGROUND OF THE INVENTION

Wafer supports are generally known to be used to support a semiconductor wafer during treatment to prevent slip and plastic deformation of the supported wafer. For example, the wafer support platform may be in the shape of a ring that is received in a slot or rests on fingers of a wafer boat. The ring has a generally planar support surface on which the wafer rests during treatment. Although the support surface is generally planar, on a microscopic scale (e.g., in terms of microns or nanometers) the surface is generally rough having a series of peaks and valleys. It is advantageous to limit the roughness (i.e., the size of the peak and valleys) of the support surface and to make the roughness uniform along the surface because a uniform surface is less likely to cause slip and plastic deformation in a wafer that is being supported by the platform.

It is generally known that the support surface of the platform can be subjected to sandblasting procedures to make the surface generally uniform. For example, U.S. Application Publication No. 2004/0089236, filed Jun. 26, 2003, describes such a procedure involving the use of silicon carbide particles to smooth the surface of a platform. While modifying the surface of the platform by sandblasting has advantages in providing a uniform roughness, what is not known to be disclosed in the prior art is the problem of small particles (i.e., contaminants) being embedded in the surface of the platform during the sandblasting procedure. For example, metal particles from a nozzle used during the sandblasting procedure and/or silicon carbide particles themselves may be embedded in the surface. This problem of particles being embedded in the surface of the platform during the sandblasting procedure is recognized, discussed and addressed by the present application.

### SUMMARY OF THE INVENTION

In one aspect of the present invention, a method of preparing a wafer support platform to be used for supporting a semiconductor wafer during treatment generally comprises sandblasting the platform to modify a surface of the platform to reduce slip of the supported wafer during treatment. The sandblasting introduces contaminants on the surface of the platform. A layer of material is applied on the surface of the platform after the sandblasting to prevent the contaminants from diffusing into the supported wafer during treatment.

In another aspect, a wafer support platform comprises a main body having a surface modified by sandblasting. Contaminants from sandblasting are embedded in the surface of the body. A layer of material overlies the contaminants on the surface of the body to prevent the contaminants from diffusing into the supported wafer during treatment.

Other features will be in part apparent and in part pointed out hereinafter.

### BRIEF DESCRIPTION OF THE DRAWINGS

FIG. 1 is a perspective of one embodiment of a wafer support platform for supporting a semiconductor wafer in a vertical wafer boat during high temperature annealing;

FIG. 2 is a perspective of a vertical wafer boat holding a plurality of wafer support platforms;

FIG. 3 is similar to FIG. 1 with a support layer of the wafer support platform exploded from a main body of the wafer support platform;

FIG. 4 is a cross-section of the wafer support platform through a groove of the support ring taken in a plane containing the line 4-4 of FIG. 1;

FIG. 5 is an enlarged, partial view of FIG. 4; and

FIG. 6 is a flow chart of a method of preparing the wafer support platform.

Corresponding reference characters indicate corresponding parts throughout the drawings.

### DETAILED DESCRIPTION OF THE DRAWINGS

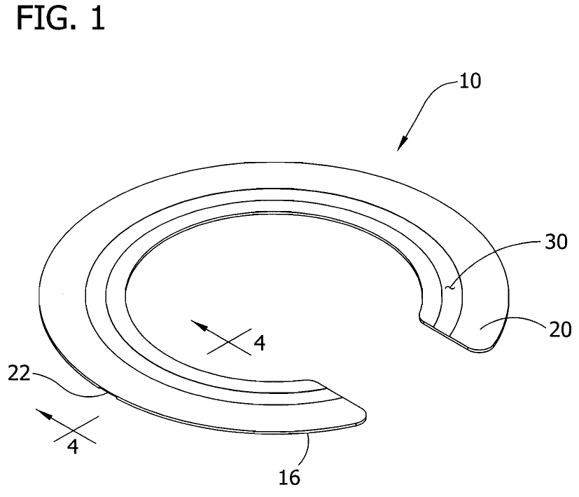

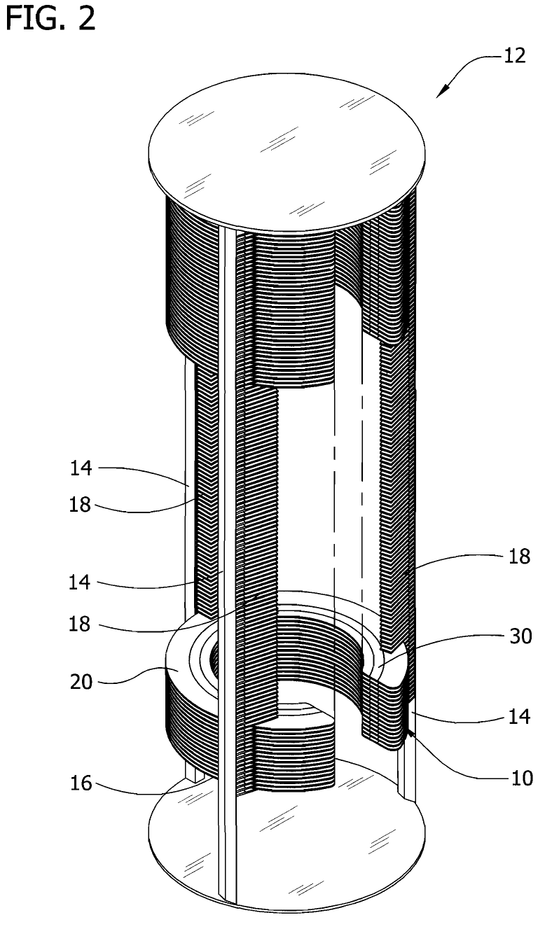

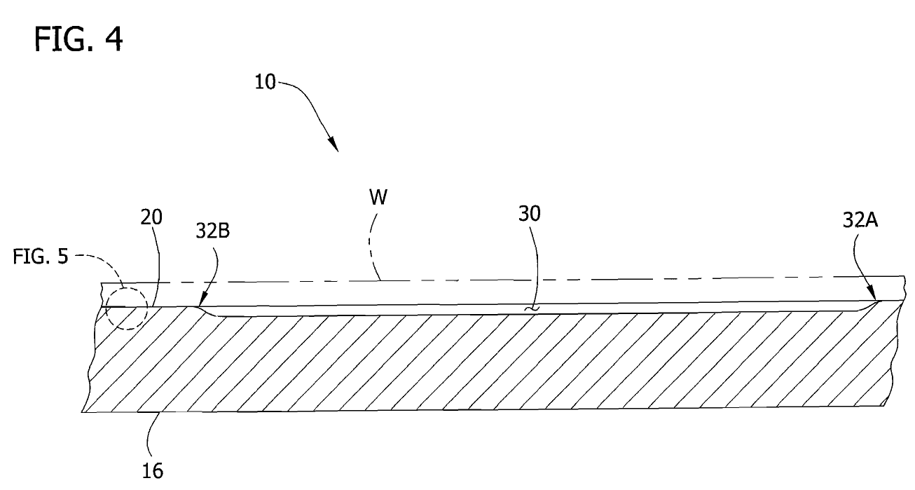

Referring now to the Figures, and in particular to FIGS. 1-3, a wafer support platform is generally indicated at reference numeral 10. As shown in FIG. 2, the illustrated wafer support platform is of the type sized and shaped to be received in a vertical wafer boat, generally indicated at 12, for supporting a semiconductor wafer W (FIG. 4) during high temperature annealing in a vertical furnace.

As shown best in FIG. 1, the platform 10 is arcuate, of the open-ring type, and is sized and shaped to be received between rails 14 of the vertical wafer boat 12. The support platform 10 may have a diameter of about 200 mm or about 300 mm or other sizes, depending on the size of the wafer to be supported thereon. The wafer support platform 10 may be of other configurations within the scope of this invention. For example, the platform 10 may be of a type for supporting a semiconductor in a structure other than a vertical furnace. Moreover, the platform 10 may be of another type besides an open-ring type.

As shown best in FIG. 2, a bottom surface 16 of the platform 10 rests on fingers 18 extending from the rails 14 of the wafer boat 12 while a support surface 20 (i.e., a top surface) of the platform supports the wafer W thereon. The bottom surface 16 of the platform 10 may have grooves 22 (only one of which is illustrated in FIG. 1) formed therein for receiving the corresponding fingers 18 of the wafer boat 12. Such a configuration is described in detail in U.S. Pat. No. 7,033,168 issued Apr. 25, 2006, the entirety of which is herein incorporated by reference. The wafer support platform 10 may be used in other types of wafer boats and holders for semiconductor wafers without departing from the scope of this invention.

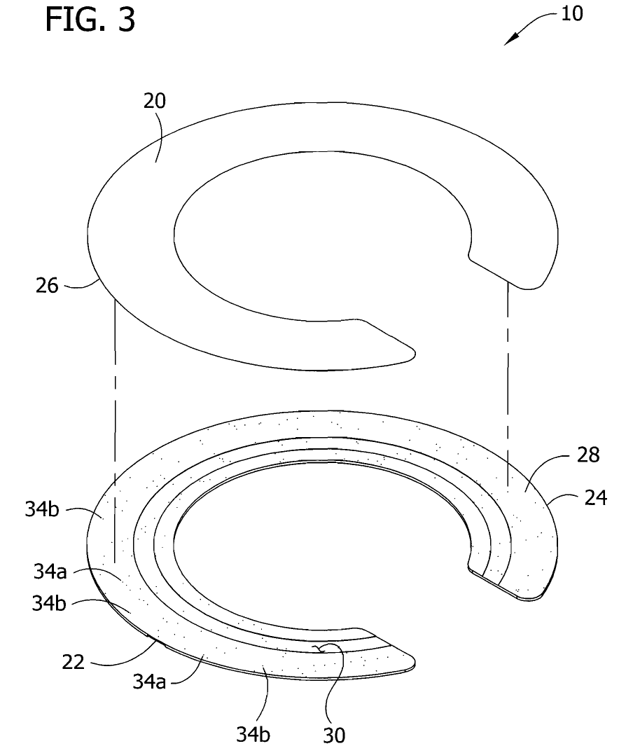

Referring now to FIGS. 3-5, the support platform 10 includes a main body 24 and a support layer 26 that defines the support surface 20. The main body 24 is composed substantially of silicon carbide, although the body may be composed substantially of silicon, for example, or other material. The main body 24 includes an upper surface 28 that is sandblasted to make the surface have a generally uniform roughness. As used herein, the term “sandblast” and related forms refer broadly to projecting a stream of solid particles (any type of solid particle) across a surface using pressurized gas, such as air. In the particular embodiment, the upper surface 28 of the body 24 is sandblasted with silicon-containing particles, such as silicon carbide particles and/or silica particles, so that the surface has a generally uniform average surface roughness of between about 0.3 microns and about 10 microns. Without being bound to a particular theory, by having a uniform roughness, the surface 28 is less likely to cause slip and plastic deformation in the supported wafer W than if the roughness of the surface was non-uniform. It is understood that the upper surface 28 may be coated with silicon carbide, such as by chemical vapor deposition, before being sandblasted. The main body 24 may be formed in other ways without departing from the scope of the invention.

An arcuate, concentric channel 30 (FIGS. 1, 3 and 4) runs along the upper surface 28 of the main body 24. Referring to FIG. 4, the channel 30 has radially spaced apart inner and outer edge margins, generally indicated at 32A, 32B, respectively. In addition to the support surface 28, the outer and inner edge margins 32A, 32B, respectively, of the channel 30 are also sandblasted so that the edge margins have a radius of curvature of about 0.5 mm, although it is contemplated that the radius of curvature may be between about 0.1 mm and about 1.0 mm.

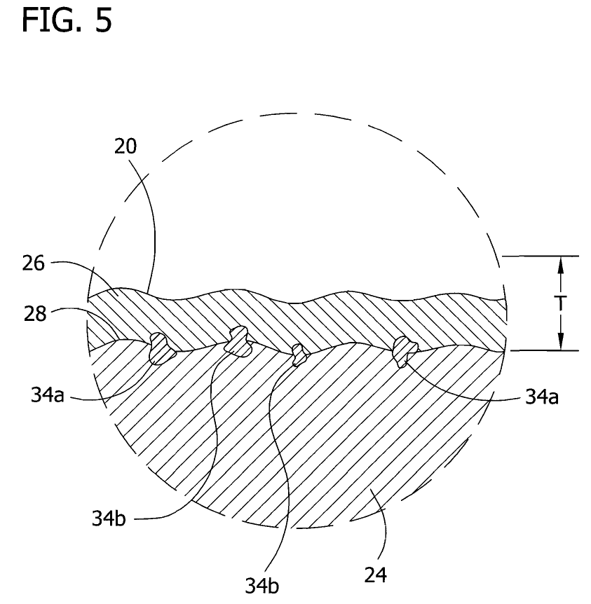

Referring to FIGS. 3 and 5, silicon-containing particles 34a and metal particles 34b, such as iron and nickel, are embedded in the upper surface 28 of the body 24. Both of these types of particles, 34a, 34b are generally referred to herein as “contaminants”. The particles 34a, 34b may be embedded in the body 24 during the sandblasting process. The silicon-containing particles 34a embedded in the upper surface 28 of the body 24 may be the silicon-containing particles used in the sandblasting procedure, as described above. Because the silicon-containing particles are traveling at such a high rate of speed, at least some of the particles (indicated in the drawings as the silicon-containing particles 34a) may become embedded in the surface 28 during the sandblasting process. Moreover, the metal particles 34b, such as iron and/or nickel, may come from a metal nozzle used during the sandblasting process. Again, because the silicon-containing particles are moving at a high rate of speed during sandblasting, the metal particles 34b may be stripped off of the nozzle during the process and become embedded in the surface 28. Conventional cleaning techniques, such as oxidation, megasonic particle removal and acid stripping are not sufficient to remove all of the particles 34a, 34b from the surface 28. It is understood that other types of particles besides silicon-containing particles 34a and metal particles 34b may be embedded in the upper surface 28, and these particles are also generally referred to herein as “contaminants”. Moreover, it is also understood that only one or some of the different types of particles, such as the silicon-containing particles 34a and the metal particles 34b, may be embedded in the upper surface 28 during the sandblasting process.

Referring to FIG. 5, the support layer 26 conformingly overlies the upper surface 28 of the main body 24, including the particles 34a, 34b, so that the support surface 20 generally retains the uniform roughness of the upper surface (i.e., the support surface generally has the same peaks and valleys as the upper surface). In other words, a topography of the support surface 20 generally corresponds to a topography of the upper surface 28. The support layer isolates the wafer W from the particles 34a, 34b when the wafer is being supported on the platform 10. Otherwise, the silicon-containing particles 34a and the metal particles 34b may stick onto the wafer W during treatment, such as during high temperature annealing, and/or the metal particles may seep into and contaminant the wafer W during treatment. The support layer 26 may be composed substantially of silicon carbide and may be applied by chemical vapor deposition. Preferably, a thickness T of the support layer 26 is such that the particles 34a, 34b embedded in the main body 24 are entirely between the support surface 20 of the support layer and the main body 24 and the topography of the support surface generally conforms to the upper surface 28 of the main body 24. The support layer 26 may have a thickness T between about 1 micron and about 200 microns, preferably between about 5 microns and about 150 microns, and more preferably between about 10 microns and about 60 microns.

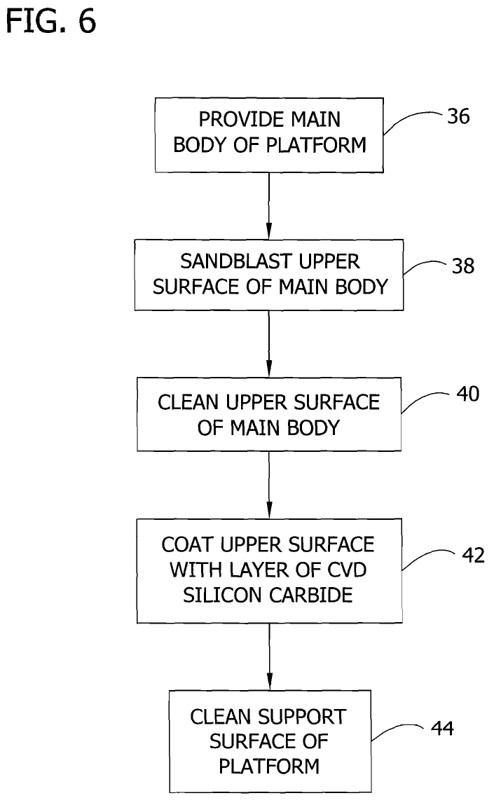

Referring now to FIG. 6, an exemplary method of making the support platform 10 will now be described. First, at step 36 the main body 24 of the support platform 10 is provided. The main body 24 may be roughly fabricated from a piece of silicon carbide, for example, into the generally size and shape of the main body. For example, the channel 30 may be formed with sharp edge margins 32A, 32B or at least edge margins not having a radius of curvature as described above. The upper surface 28 of the main body 24 is coated, such as by chemical vapor deposition, with a layer of silicon carbide. At this point, the upper surface 28 of the main body 24 has a generally non-uniform roughness due to the chemical vapor deposition.

At step 38, the upper surface 28 is sandblasted with silicon carbide particles to make the surface have a generally uniform roughness, such as described above. The edge margins 32A, 32B of the channel 30 are also sandblasted to increase the radii of curvature of the edges. The sandblasting process entails mixing the silicon-containing particles (e.g., silicon carbide particles and/or silica particles) in a pressurized medium (e.g., air) and projecting the mixture at a high velocity out of a metal nozzle. The silicon-containing particles 34a and/or the metal particles 34b become embedded in the upper surface 28 of the main body 24 during sandblasting.

After sandblasting, the upper surface 28 of the main body 24 is cleaned at step 40 to remove those particles 34a, 34b that are removable, e.g., contaminants that are not completely embedded in the body. As an example, the body 24 may be cleaned by subjecting it to oxidation at 1100° C. and then stripping the particles 34a, 34b from the upper surface 28 with hydrofluoric acid. Additionally, megasonic particle removal including a mixture of ammonia, hydrogen peroxide and water, and hydrofluoric acid and hydrochloric acid stripping may be performed. Other cleaning procedures may be used.

After cleaning, the upper surface 28 of the main body 24 is coated with silicon carbide at step 42. High purity silicon carbide is applied by chemical vapor deposition so that the support layer 26 has a thickness T as described above to isolate the particles 34a, 34b from the support surface 20 and the wafer W that is supported on the surface and to ensure that the support surface 20 has generally the same uniform roughness as the upper surface 28. The platform 10 may then be cleaned again at step 44 using the same cleaning procedures outlined above.

When introducing elements of the present invention or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions, products, and methods without departing from the scope of the invention, it is intended that all matter contained in the above description and shown in the accompanying drawings shall be interpreted as illustrative and not in a limiting sense.

What is claimed is:

1. A method of preparing a wafer support platform to be used for supporting a semiconductor wafer during treatment, said method comprising
sandblasting a surface of the platform to reduce slip of the supported wafer during treatment, wherein the sandblasting introduces contaminants on the surface of the platform,
applying a layer of a material on the surface of the platform after said sandblasting to prevent the contaminants from diffusing into the supported wafer during treatment.

2. A method of preparing a wafer support platform as set forth in claim 1 wherein said sandblasting comprises altering the surface of the platform so that it has a generally uniform roughness.

3. A method of preparing a wafer support platform as set forth in claim 2 wherein said applying a layer of material comprises conformingly applying the layer of material so that a support surface of the layer generally has the same uniform roughness as the surface of the platform.

4. A method of preparing a wafer support platform as set forth in claim 2 wherein said applying a layer comprises applying a layer of at least one of silicon carbide and silicon on the surface of the platform.

5. A method of preparing a wafer support platform as set forth in claim 2 wherein said applying a layer further comprises applying the layer by chemical vapor deposition.

6. A method of preparing a wafer support platform as set forth in claim 5 wherein the applied layer has a thickness of between about 1 micron and about 100 microns.

7. A method of preparing a wafer support platform as set forth in claim 5 wherein the applied layer has a thickness of between about 10 microns and about 60 microns.

8. A method of preparing a wafer support platform as set forth in claim 5 further comprising removing at least some of the contaminants from the wafer platform after said sandblasting and before said applying a layer of material.

9. A wafer support platform comprising
a main body having a surface modified by sandblasting,
contaminants from sandblasting embedded in the surface of the body,
a layer of material overlying the contaminants on said surface of the body to prevent the contaminants from diffusing into the supported wafer during treatment.

10. A wafer support platform as set forth in claim 9 wherein the surface of the main body has a generally uniform roughness and wherein the layer of material has a support surface with generally the same inform roughness as the surface of the main body.

11. A wafer support platform as set forth in claim 9 wherein said body is constructed at least in part of at least one of silicon and silicon carbide, and wherein said layer of material is at least one of silicon carbide and silicon.

12. A wafer support platform as set forth in claim 11 wherein said layer of material is deposited on the surface by chemical vapor deposition.

13. A wafer support platform as set forth in claim 12 wherein the contaminants include at least one of metal particles and silicon-containing particles.

14. A wafer support platform as set forth in claim 13 wherein the body includes a groove, an edge of the groove being modified by sandblasting and the layer of material overlying contaminants on the edge of the groove.

15. A wafer support platform as set forth in claim 12 wherein said layer of material has an average thickness of between about 1 micron and about 100 microns.

16. A wafer support platform as set forth in claim 15 wherein said layer of material has an average thickness of between about 10 microns and about 60 microns.

17. A wafer support platform as set forth in claim 11 wherein the surface of the platform has an average surface roughness between about 0.3 and 10 microns.
